(19) United States
(12) Patent Application Publication
(10) Pub. No.: US 2005/0270072 A1
(43) Pub. Date: Dec. 8, 2005

(54) DIGITAL PHASE FREQUENCY DISCRIMINATOR

(76) Inventor: Te-Chih Chang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/710,664

(22) Filed: Jul. 28, 2004

(30) Foreign Application Priority Data
Jun. 3, 2004 (TW) 093115998

(51) Int. Cl. H03D 13/00

(52) U.S. Cl. 327/40

(57) ABSTRACT

A digital phase frequency discriminator has a first SR latch for generating a first output signal when set to a predetermined state, a second SR latch for generating a second output signal when set to the predetermined state, a predetermined state-detecting circuit for detecting the first and the second output signals and for outputting an RCM signal, a first predetermined state control circuit for setting the first SR latch to the predetermined state according to the RCM signal, and a second predetermined state control circuit for setting the second SR latch to the predetermined state according to the RCM signal. Both the first SR latch and the first predetermined state control circuit have a first inputting terminal for receiving a first input signal, and both the second SR latch and the second predetermined state control circuit have a second inputting terminal for receiving a second input signal.

### BACKGROUND OF INVENTION

1. Field of the Invention

The present invention relates to a digital phase frequency discriminator (DPFD), and more particularly, to a DPFD having a simplified structure.

2. Description of the Prior Art

A digital phase frequency discriminator (DPFD) typically provides an output, which is related to a phase or frequency relationship between signals input into the discriminator. For example, in a phase lock loop a DPFD is often used to compare a reference signal to a signal derived from the output of a voltage-controlled oscillator (VCO) to detect the phase or frequency difference between the two signals and to provide an output signal which is related to this difference. The frequency of oscillation of the VCO then can be changed based upon the output signal to decrease this difference. In this manner, the phase or frequency difference between the signals received by the DPFD can be reduced until it becomes substantially zero, indicating that the phase lock loop is substantially in phase lock.

A variety of DPFDs have been disclosed. Please refer to FIG. 1, which is a circuit diagram of a DPFD 10 according to the prior art. The DPFD 10 comprises a first SR latch 12, a second SR latch 14, a third SR latch 16, and a fourth SR latch 18, each of which comprise a pair of two-input cross-coupled NOR gates.

The first SR latch 12 comprises a first NOR gate 20 and a second NOR gate 22, each of which comprises two input ends. One input end of the first NOR gate 20 serves as an S input end of the first SR latch 12, and one input end of the second NOR gate 22 serves as an R input end of the first SR latch 12. The other input end of the first NOR gate 20 is cross-coupled to an output end of the second NOR gate 22, and the other input end of the second NOR gate 22 is cross-coupled to an output end of the first NOR gate 20. The output end of the first NOR gate 20 provides a \overline{Q}

output signal, and the output end of the second NOR gate 22 provides a Q output signal.

Similarly, the second SR latch 14 comprises a third NOR gate 24 and a fourth NOR gate 26, each of which comeprises two input ends. One input end of the third NOR gate 24 serves as an S input end of the second SR latch 14, and one input end of the fourth NOR gate 26 serves as an R input end of the second SR latch 14. The other input end of the third NOR gate 24 is cross-coupled to an output end of the fourth NOR gate 26, and the other input end of the fourth NOR gate 26 is cross-coupled to an output end of the third NOR gate 24. The output end of the third NOR gate 24 provides a \overline{Q}

output signal, and the output end of the fourth NOR gate 26 provides a Q output signal.

The third SR latch 16 comprises a fifth NOR gate 28 and a sixth NOR gate 30, each of which comprises two input ends. One input end of the fifth NOR gate 28 serves as an S input end of the third SR latch 16, and is coupled to the \overline{Q}

output signal end of the first SR latch 12. One input end of the sixth NOR gate 30 serves as an R input end of the third SR latch 16. The other input end of the fifth NOR gate 28 is cross-coupled to an output end of the sixth NOR gate 30, and the other input end of the sixth NOR gate 30 is cross-coupled to an output end of the fifth NOR gate 28. The output end of the fifth NOR gate 28 provides a \overline{Q}

output signal, and the output end of the sixth NOR gate 30 provides a Q output signal.

Similarly, the fourth SR latch 18 comprises a seventh NOR gate 32 and an eighth NOR gate 34, each of which comprises two input ends. One input end of the seventh NOR gate 32 serves as an S input end of the fourth SR latch 18, and is coupled to the \overline{Q}

output signal end of the second SR latch 14. One input end of the eighth NOR gate 34 serves as an R input end of the fourth SR latch 18. The other input end of the seventh NOR gate 32 is cross-coupled to an output end of the eighth NOR gate 34, and the other input end of the eighth NOR gate 34 is cross-coupled to an output end of the seventh NOR gate 32. The output end of the seventh NOR gate 32 provides a \overline{Q}

output signal, and the output end of the eighth NOR gate 34 provides a Q output signal.

The S input end of the first NOR gate 20 receives a first input signal I₁, and the S input end of the third NOR gate 24 receives a second input signal I₂, which is asynchronous to the first input signal I₁. The \overline{Q}

output signal end of the third SR latch 16 is coupled to the R input end of the first SR latch 12, and the \overline{Q}

output signal end of the fourth SR latch 18 is coupled to the R input end of the second SR latch 14. The Q output signal end of the first SR latch 12 provides a first output signal O₁, and the Q output signal end of the second SR latch 14 provides a second output signal O₂.

The DPFD 10 further comprises a reset NOR gate 36, which provides reset signal (RCM signal) to the third and fourth SR latches 16 and 18. More particularly, the reset NOR gate 36 comprises a first input end 38 coupled to the \overline{Q}

output signal end of the first SR latch 12, a second input end 40 coupled to the \overline{Q}

output signal end of the second SR latch 14, and an output end 42 coupled to the R input ends of the third and fourth SR latches 16 and 18.

Please refer to FIG. 2, which is a timing diagram illustrating the first and second input signals I₁ and I₂, the first and second output signals O₁ and O₂, and the RCM signal of the DPFD 10 according to the prior art. The operation of the DPFD 10 will be understood from the following description in conjunction with the illustrative timing diagram of FIG. 2.

In the exemplary timing diagram of FIG. 2, both the first and second SR latches 12 and 14 initially at time T₀ are in their reset condition: the Q output signal end in a logical state 0 and the \overline{Q}

output signal end in a logical state 1. Thus, initially both the first and second output signals O₁ and O₂ and RCM signal are also in the logical state 0. Furthermore, both the third and fourth SR latches 16 and 18 initially at time T₀ are in their set condition: the Q output signal end in the logical state 1 and the \overline{Q}

output signal end in the logical state 0. Finally, both the first and second input signals I₁ and I₂ initially at time T₀ are in the logical state 0.

At time T₁, the first input signal I₁ changes from the logical 0 to the logical state 1. Consequently, the first SR latch 12 becomes set, and the first output signal O₁, however, does not change from the logical state 0 to the logical state 1 until time T₂ due to the inversion gate propagation delay of the first and second NOR gate 20 and 22. In general, logic signals suffer from timing jitter after traveling through logic gates. Since the first input signal I₁ has to travel through two logic gates, the first and second NOR gates 20 and 22, to attain the Q output signal end of the first SR latch 12, the Q output signal end suffers from two-fold logic gate timing jitter after the first SR latch 12 has been changed from reset to set. The second output signal O₂ at time T₂, however, remains unchanged. One will appreciate that any additional changes in the logical state of the first input signal I₁ at this point, without a change in the logical state of the second input signal I₂, will produce no further changes in the set or reset conditions of any of the four SR latches.

At time T₃, the second input signal I₂ changes from the logical state 0 to the logical state 1. Consequently, the second SR latch 14 becomes set, and the second output signal O₂, however, does not change from the logical state 0 to the logical state 1 until time T₄ due to the inversion gate propagation delay of the third and fourth NOR gate 24 and 26. Similarly, since the second input signal I₂ has to travel through two logic gates, the third and fourth NOR gates 24 and 26, to attain the Q output signal end of the second SR latch 14, the Q output signal end also suffers from two-fold logic gate timing jitter after the second SR latch 14 has been changed from reset to set. At time T₄, both of the input signals provided to the input ends of the reset NOR gate 36 have changed from the logical state 1s to the logical state 0s, resulting in the output end 42 of the reset NOR gate 36 to provide a logical state 1 signal to the R input ends of the third and fourth SR latches 16 and 18 at time T_{RCM} that is a little bit later than time T₄. Consequently, both the third and fourth latches 16 and 18 become reset.

Following this reset, the third SR latch 16 provides a logical state 1 signal to the R input end of the first SR latch 12, and the fourth SR latch 18 provides a logical state 1 signal to the R input end of the second SR latch 14. Thus, at time T₅ both the first and second output signals O₁ and O₂ respectively provided by the first and second SR latches 12 and 14 change from the logical state 1 to the logical state 0.

Referring to the first and third SR latches 12 and 16, since the RCM signal output from the NOR gate 36 has to travel through the sixth, fifth, and second NOR gates 30, 28, and 22 sequentially to attain the Q output signal end of the first SR latch 12, the Q output signal end of the first SR latch 12 suffers from three-fold logic gate timing jitter after the first SR latch 12 has been changed from set to reset.

The timing jitter on the first and second output signals O₁ and O₂ enables a charge pump electrically connected to the DPFD 10 to pump too much or too little charge to a specific circuit electrically connected to the charge pump.

Please refer to FIG. 3, which is a circuit diagram of a prior art DPFD 1 according to U.S. Pat. No. 3,610,954 “PHASE COMPARATOR USING LOGIC GATES”. The DPFD 1 comprises a plurality of logic gates (NAND gates) for comparing two input signals f₁ and f₂ respectively input to two input ends 2 and 3, and for outputting two output signals via two output ends 4 and 5. An RCM signal generated by a NAND gate 6 has to travel through only one logic gate, i.e. a NAND gate 9, to attain the output end 4. The output end 9 suffers from one-fold logic gate timing jitter. The DPFD 1 solves the problem that the Q output signal ends of the DPFD 10 suffer too much timing jitter. However, the DPFD 1 still suffers from another problem of crossover distortion when one input signal f₁ is approximately synchronous to the other input signal f₂.

Please refer to FIG. 4, which is a circuit diagram of a prior art DPFD 11 of U.S. Pat. No. 4,928,026 “DIGITAL PHASE COMPARING CIRCUIT”. The DPFD 11 comprises a plurality of logic gates for comparing two input signals IN₁ and IN₂ respectively input to two input ends S1 and S₂, and for generating four output signals OUT₁, OUT₂, OUT₃, and OUT₄ via four output ends S₅, S₆, S₇, and S₈ respectively. Another RCM signal generated by a NAND gate 13 has to travel through two NAND gates 15 and 17 to attain the output end S₆, which therefore suffers two-fold logic gate timing jitter, which is less than three-fold logic gate timing jitter that the Q output signal ends of the DPFD 10 suffer. However, in contrast to the DPFD 10 consisting of nine logic gates, the DPFD 11 needs as many as 11 logic gates installed.

### SUMMARY OF INVENTION

It is therefore a primary objective of the claimed invention to provide a DPFD having a simplified structure and suffering from little timing jitter.

According to the claimed invention, the DPFD includes a first SR latch, a second SR latch, a predetermined state detection circuit, a first predetermined state control circuit, and a second predetermined state control circuit. The first SR latch generates a first output signal when being set to a predetermined state and comprises a first input end for receiving a first input signal. The second SR latch generates a second output signal when being set to the predetermined state and comprises a first input end for receiving a second input signal. The predetermined state detection circuit is electrically connected to the first and the second SR latches for detecting the first and the second output signals and for outputting an RCM signal. The first predetermined state control circuit is electrically connected to the predetermined state detection circuit and the first SR latch for setting the first SR latch to the predetermined state according to the RCM signal. The first predetermined state control circuit comprises a first input end for receiving the first input signal and a second input end for receiving the RCM signal. The second predetermined state control circuit is electrically connected to the predetermined state detection circuit and the second SR latch for setting the second SR latch to the predetermined state according to the RCM signal. The second predetermined state control circuit comprises a first input end for receiving the second input signal and a second input end for receiving the RCM signal.

These and other objectives of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a circuit diagram of a DPFD according to the prior art.

FIG. 2 is a timing diagram of a plurality of signals of the DPFD shown in FIG. 1.

FIG. 3 and FIG. 4 are two circuit diagrams of two other DPFDs according to the prior art.

FIG. 5 is a circuit diagram of a DPFD of the preferred embodiment according to the present invention.

FIG. 6 is a timing diagram of a plurality of signals of the DPFD shown in FIG. 5.

FIG. 7 is a circuit diagram of a DPFD of a second embodiment according to the present invention.

FIG. 8 is a circuit diagram of a DPFD of a third embodiment according to the present invention.

FIG. 9 is a timing diagram of a plurality of signals of the DPFD shown in FIG. 8.

FIG. 10 is a circuit diagram of a DPFD of a fourth embodiment according to the present invention.

FIG. 11 is a circuit diagram of a DPFD of a fifth embodiment according to the present invention.

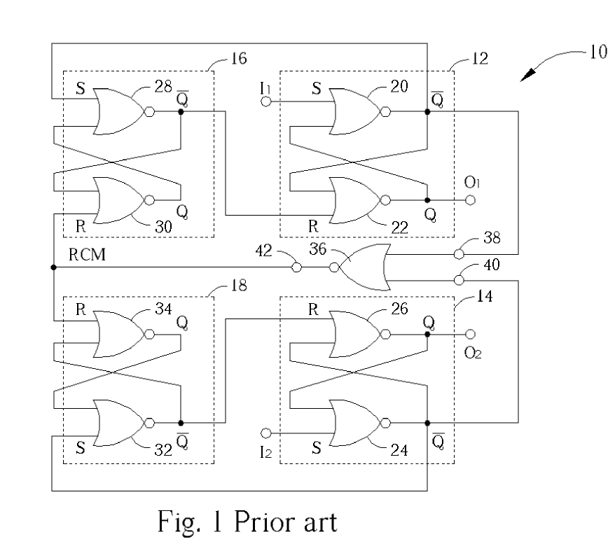

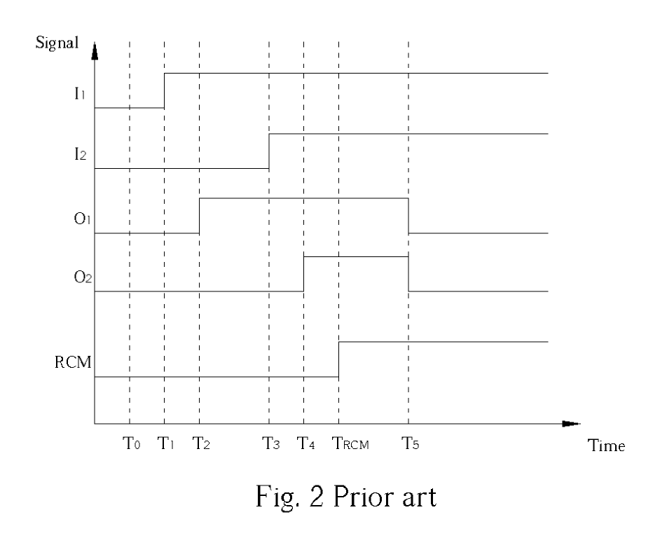

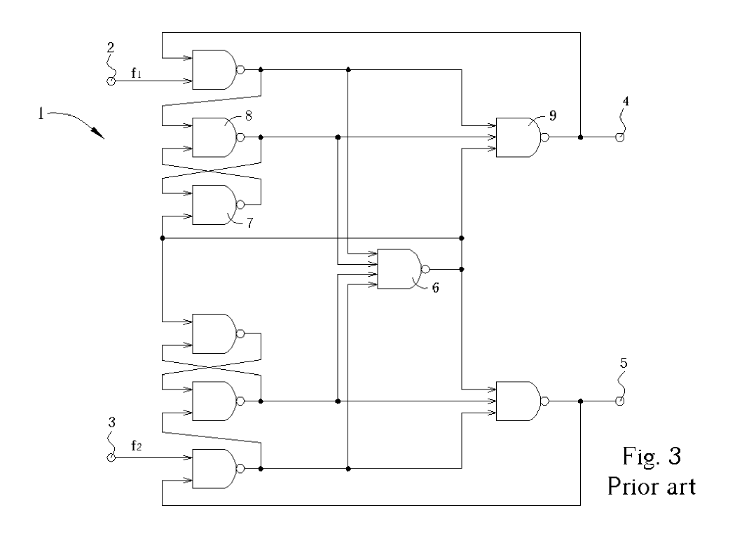

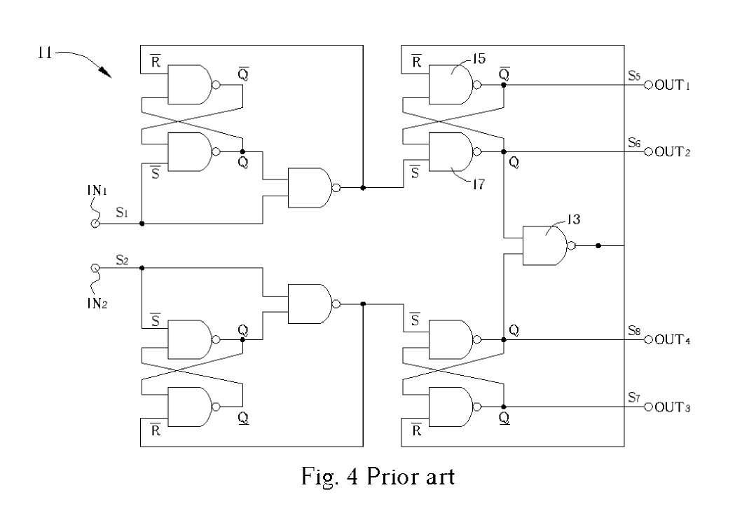

### DETAILED DESCRIPTION

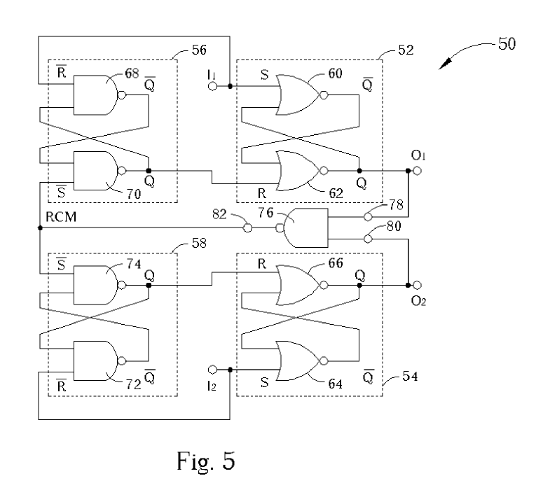

Please refer to FIG. 5, which is a circuit diagram of a DPFD 50 of the preferred embodiment according to the present invention. The DPFD 50 comprises a first SR latch 52, a second SR latch 54, a third SR latch 56, and a fourth SR latch 58. Both of the first and second SR latches 52 and 54 comprise a pair of two-input cross-coupled NOR gates. Both of the third and fourth SR latches 56 and 58 comprise a pair of two-input cross-coupled NAND gates.

The first SR latch 52 comprises a first NOR gate 60 and a second NOR gate 62, each of which comprises two input ends. One input end of the first NOR gate 60 serves as an S input end of the first SR latch 52, and one input end of the second NOR gate 62 serves as an R input end of the first SR latch 52. The other input end of the first NOR gate 60 is cross-coupled to an output end of the second NOR gate 62, and the other input end of the second NOR gate 62 is cross-coupled to an output end of the first NOR gate 60. The output end of the first NOR gate 60 provides a \overline{Q}

output signal, and the output end of the second NOR gate 62 provides a Q output signal.

Similarly, the second SR latch 54 comprises a third NOR gate 64 and a fourth NOR gate 66, each of which comprises two input ends. One input end of the third NOR gate 64 serves as an S input end of the second SR latch 54, and one input end of the fourth NOR gate 66 serves as an R input end of the second SR latch 54. The other input end of the third NOR gate 64 is cross-coupled to an output end of the fourth NOR gate 66, and the other input end of the fourth NOR gate 66 is cross-coupled to an output end of the third NOR gate 64. The output end of the third NOR gate 64 provides a \overline{Q}

output signal, and the output end of the fourth NOR gate 66 provides a Q output signal.

The third SR latch 56 comprises a first NAND gate 68 and a second NAND gate 70, each of which comprises two input ends. One input end of the first NAND gate 68 serves as an \overline{R}

input end of the third SR latch 56, and is coupled to the S input end of the first SR latch 52. One input end of the second NAND gate 70 serves as an \overline{S}

input end of the third SR latch 56. The other input end of the first NAND gate 68 is cross-coupled to an output end of the second NAND gate 70, and the other input end of the second NAND gate 70 is cross-coupled to an output end of the first NAND gate 68. The output end of the first NAND gate 68 provides a \overline{Q}

output signal, and the output end of the second NAND gate 70 provides a Q output signal.

The fourth SR latch 58 comprises a third NAND gate 72 and a fourth NAND gate 74, each of which comprises two input ends. One input end of the third NAND gate 72 serves as an \overline{R}

input end of the fourth SR latch 58, and is coupled to the S input end of the second SR latch 54. One input end of the fourth NAND gate 74 serves as an \overline{S}

input end of the fourth SR latch 58. The other input end of the third NAND gate 72 is cross-coupled to an output end of the fourth NAND gate 74, and the other input end of the fourth NAND gate 74 is cross-coupled to an output end of the third NAND gate 72. The output end of the third NAND gate 72 provides a \overline{Q}

output signal, and the output end of the fourth NAND gate 74 provides a Q output signal.

The S input end of the first SR latch 52 receives a first input signal I₁, and the S input end of the second SR latch 54 receives a second input signal I₂. The Q output signal end of the third SR latch 56 is coupled to the R input end of the first SR latch 52, and the Q output signal end of the fourth SR latch 58 is coupled to the R input end of the second SR latch 54. The Q output signal end of the first SR latch 52 provides a first output signal O₁, and the Q output signal end of the second SR latch 54 provides a second output signal O₂.

The DPFD 50 further comprises a reset NAND gate 76 to provide reset signal (RCM signal) to the third and fourth SR latches 56 and 58. More particularly, the reset NAND gate 76 comprises a first input end 78 coupled to the Q output signal end of the first SR latch 52, a second input end 80 coupled to the Q output signal end of the second SR latch 54, and an output end 82 coupled to the \overline{S}

input ends of the third and fourth SR latches 56 and 58.

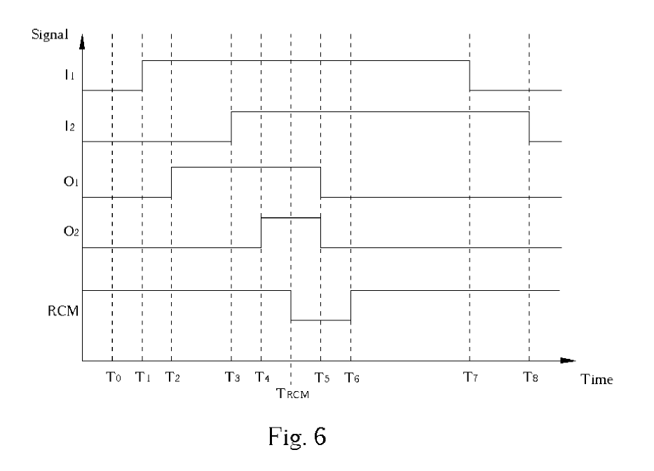

Please refer to FIG. 6, which is a timing diagram illustrating the first and second input signals I₁ and I₂, the first and second output signals O₁ and O₂, and the RCM signal of the DPFD 50 according to the present invention. The operation of the DPFD 50 will be understood from the following description in conjunction with the illustrative timing diagram of FIG. 6.

In the exemplary timing diagram of FIG. 6, the first and second SR latches 52 and 54 initially at time T₀ are in their reset condition. Thus, initially both the first and second output signals O₁ and O₂ are in the logical state 0. Furthermore, both the third and fourth SR latches 56 and 58 initially are also in their reset condition. Finally, both the first and second input signals I₁ and I₂ initially at time T₀ are in the logical state 0.

At time T₁, the first input signal I₁ changes from the logical state 0 to the logical state 1. Consequently, the first SR latch 52 becomes set, and at time T₂ the first output signal O₁ changes from the logical state 0 to a logical state 1. The second output signal O₂ at time T₂ remains unchanged. One will appreciate that any additional changes in the logical state of the first input signal I₁ at this point, without a change in the logical state of the second input signal I₂, will produce no further changes in the set or reset conditions of any of the four SR latches.

At time T₃, the second input signal I₂ changes from the logical state 0 to the logical state 1. Consequently, the second SR latch 54 becomes set, and at time T₄ the second output signal O₂ changes from the logical state 0 to the logical state 1. At time T₄, the input signals provided to the input ends of the reset NAND gate 76 both have become logical state 1s, resulting the output end 82 to provide a logical state 0 signal to the \overline{S}

ends of the third and fourth SR latches 56 and 58 at time T_{RCM} a little bit later than time T₄. Consequently, both the third and fourth SR latches 56 and 58 become set.

Following this set, the third SR latch 56 provides a logical state 1 signal to the R input end of the first SR latch 52, and the fourth SR latch 58 also provides a logical state 1 signal to the R input end of the second SR latch 54. Thus, at time T₅ the first and second output signals O₁ and O₂ provided by the first and second SR latches 52 and 54 change from the logical state 1 to the logical state 0. At time T₆, the RCM signal output from the reset NAND gate 76 changes from the logical state 0 to the logical state 1.

Referring to the first and third SR latches 52 and 56, since the RCM signal output from the NAND gate 76 has to travel through the second NAND gate 70 and the second NOR gate 62 sequentially to attain the Q output signal end of the first SR latch 52, the Q output signal ends of the first and second SR latches 52 and 54 suffer from two-fold logic gate timing jitter, which is less than three-fold logic gate timing jitter that the Q output signal ends of the DPFD 10 suffer.

Accordingly, it will be appreciated that at time T₇, when the first input signal I₁ changes from the logical state 1 to the logical state 0, the third latch 56 will become reset again, and its Q output will transit to the logical state 0. Similarly, at time T₈ the second input signal I₂ changes from the logical state 1 to the logical state 0, the fourth latch 58 will become reset again, and its Q output will transit to the logical state 0. In summary, after time T₈ the DPFD 50 of the present invention is ready to respond to the next series of input signals.

Although the operation of a DPFD of the present invention is explained with regard to the preferred embodiment 50, which comprises the first and second SR latches 52 and 54, each of which comprises two cross-coupled NOR gates, and the third and fourth SR latches 56 and 58, each of which comprises two cross-coupled NAND gates, and the reset gate 76, which comprises the NAND gate 76 for detecting the first and second output signals O₁ and O₂, it will be appreciated that the remaining embodiments each operate based upon similar principles which will be understood by those skilled in the art. Additionally, it will be understood that the following description of the operation of the present invention applies positive logic, all of the SR latches functioning only during a period that the first input signal I₁ or the second input signal I₂ changes from the logical state 0 to the logical state 1, and that an equivalent description could be set forth using negative logic.

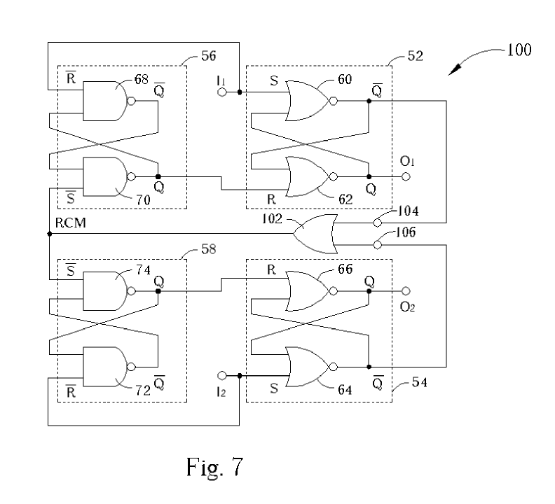

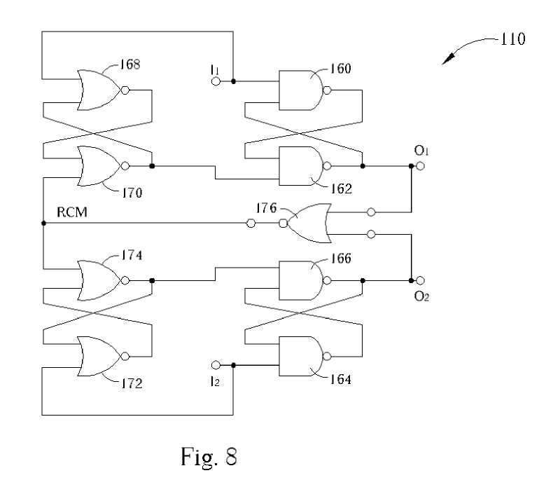

Please refer to FIG. 7 and FIG. 8, which are two circuit diagrams of two DPFDs 100 and 110, both of which are derived from the DPFD 50, according to the present invention.

Of the DPFD 100, an OR gate 102 substitutes for the NAND gate 76 of the DPFD 50. The OR gate 102 comprises a first input end 104 coupled to the \overline{Q}

output signal end of the first SR latch 52, and a second input end 106 coupled to the \overline{Q}

output signal end of the second SR latch 54.

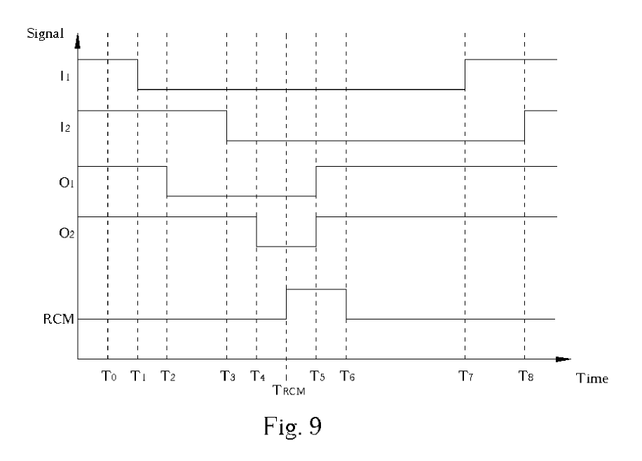

Of the DPFD 110, four NAND gates 160, 162, 164, and 166 substitute for the four NOR gates 60, 62, 64, and 66 respectively, four NOR gates 168, 170, 172, and 174 substitute for the four NAND gates 68, 70, 72, and 74 respectively, and a NOR gate 176 substitutes for the NAND 76. In operation, the first and second input signals I₁ and I₂, the first and second output signals O₁ and O₂, and the RCM signal are illustrated in FIG. 9. Because the DPFD 110 has an operation mechanism similar to that of the DPFD 50, detailed description is hereby omitted. Note that, of the DPFD 110, at time T₀ all of the SR latches are set. The first and second input signals I₁ and I₂ use negative logic. Both the first and second output signals O₁ and O₂ have a logical state changed during a period that the first or second input signals I₁ or I₂ changes from the logical state 1 to the logical state 0.

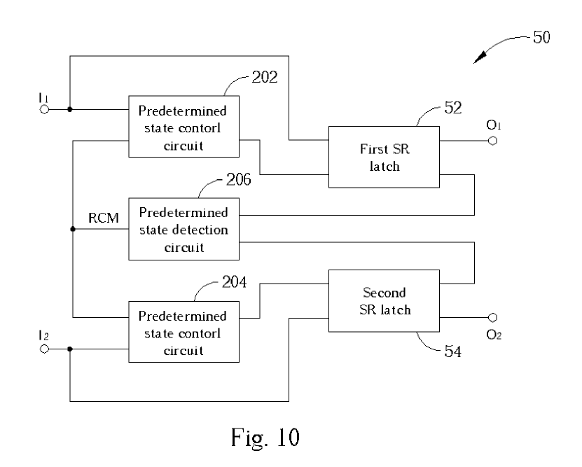

Of the DPFD 50 (also of the DPFDs 100 and 110), the reset NAND gate 76 generates the RCM signal according to the first and second output signals O₁ and O₂, and both the third and fourth SR latches 56 and 58 generate reset signals to reset the first and second SR latches 52 and 54 respectively according to the RCM signal output from the reset NAND gate 76. In equivalence, the third and fourth SR latches 56 and 58 can be regarded as two predetermined state (reset) control circuits to generate predetermined state signals (reset signals), and the reset NAND gate 76 can be regarded as a predetermined state detection circuit to detect the first and second output signals O₁ and O₂ and to output the RCM signal. In essence, the DPFD 50, as well as the DPFDs 100 and 110, can be simplified to a circuit having a plurality of function-specified blocks shown in FIG. 10.

Please refer to FIG. 10, which is a function block diagram of the DPFD 50 (DPFDs 100 and 110) according to the present invention. The DPFD 50 comprises two predetermined state control circuits 202 and 204, a predetermined state detection circuit 206, the first SR latch 52, and the second SR latch 54. Different from the DPFD 10, whose predetermined state control circuits (the third and fourth SR latches 16 and 18) are controlled by the first and second SR latches 12 and 14, the DPFDs of the present invention have the predetermined state control circuits 202 and 204 be controlled by the first and second input signals I₁ and I₂.

Please refer to FIG. 6 again, at time T₄, when the second output signal O₂ changes from the logical state 0 to the logical state 1, neither the first nor second output signal O₁ nor O₂ become reset immediately, namely, neither the first nor second output signal O₁ nor O₂ change from the logical state 1 to the logical state 0 immediately. Both the first and second output signals O₁ and O₂ do not change from the logical state 1 to the logical state 0 until at least a reset period from time T₄ to time T₅ passed, and the reset period has to be long enough for the first and second output signals O₁ and O₂ to reach to a full logical state 1 amplitude level before changing from the logical state 1 to the logical state 0.

How long the reset period should be relates to the characteristics of the predetermined state detection circuit and the connection between the SR latches of the DPFD 50. The purpose that the reset period has to be longer than a predetermined period is to prevent the problem of crossover distortion when the first input signal I₁ is approximately synchronous to the second input signal I₂.

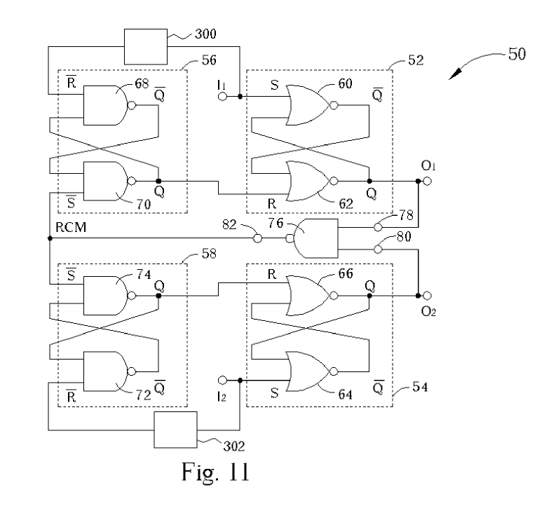

Additionally, in order to prevent “race” phenomenon from appearing at the first and second SR latches 52 and 54, two delay components 300 and 302 are introduced to the DPFD 50. As shown in FIG. 11, the delay component 300 is installed between the S input end of the first SR latch 52 and the \overline{R}

input end of the third SR latch 56, and the delay component 302 is installed between the S input end of the second SR latch 54 and the \overline{R}

input end of the fourth SR latch 58.

In contrast to the prior art, the present invention can provide a DPFD comprising two predetermined state control circuits, a predetermined state detection circuit, and two SR latches. Since both of the predetermined state control circuits are directly controlled by two input signals, the output ends of the SR latches suffer from only two-fold logic gate timing jitter.

Following the detailed description of the present invention above, those skilled in the art will readily observe that numerous modifications and alterations of the device may be made while retaining the teachings of the invention. Accordingly, the above disclosure should be construed as limited only by the metes and bounds of the appended claims.

1. A digital phase frequency discriminator (DPFD) comprising:
a first SR latch for generating a first output signal when being set to a predetermined state, the first SR latch comprising a first input end for receiving a first input signal;
a second SR latch for generating a second output signal when being set to the predetermined state, the second SR latch comprising a first input end for receiving a second input signal;
a predetermined state detection circuit electrically connected to the first and the second SR latches for detecting the first and the second output signals and for outputting an RCM signal;
a first predetermined state control circuit electrically connected to the predetermined state detection circuit and the first SR latch for setting the first SR latch to the predetermined state according to the RCM signal, the first predetermined state control circuit comprising a first input end for receiving the first input signal, and a second input end for receiving the RCM signal; and
a second predetermined state control circuit electrically connected to the predetermined state detection circuit and the second SR latch for setting the second SR latch to the predetermined state according to the RCM signal, the second predetermined state control circuit comprising a first input end for receiving the second input signal, and a second input end for receiving the RCM signal.

2. The DPFD of claim 1 further comprising a first delay component electrically connected between the first input end of the first predetermined state control circuit and the first input end of the first SR latch.

3. The DPFD of claim 2 further comprising a second delay component electrically connected between the first input end of the second predetermined state control circuit and the first input end of the second SR latch.

4. The DPFD of claim 1, wherein the predetermined state detection circuit comprises a NAND gate.

5. The DPFD of claim 4, wherein the first SR latch comprises a Q output signal end, the second SR latch comprises a Q output signal end, and the NAND gate comprises two input ends electrically connected to the two Q output signal ends respectively.

6. The DPFD of claim 1, wherein the predetermined state detection circuit comprises an OR gate.

7. The DPFD of claim 6, wherein the first SR latch comprises a \overline{Q}
output signal end, the second SR latch comprises a \overline{Q}
output signal end, and the OR gate comprises two input ends electrically connected to the two \overline{Q}
output signal ends respectively.

8. The DPFD of claim 1, wherein both the first and the second SR latches comprise a pair of cross-coupled NOR gates.

9. The DPFD of claim 1, wherein both the first and the second SR latches comprise a pair of cross-coupled NAND gates.

10. The DPFD of claim 1, wherein both the first and the second predetermined state control circuits comprise a pair of cross-coupled NAND gates.

11. The DPFD of claim 1, wherein both the first and the second predetermined state control circuits comprise a pair of cross-coupled NOR gates.
